(19) United States
(12) Patent Application Publication
(10) Pub. No.: US 2026/0037704 A1
(43) Pub. Date: Feb. 5, 2026

(54) FLUID ANALYSIS METHOD

(71) Applicant: SAMSUNG ELECTRONICS CO., LTD., Suwon-si (KR)

(72) Inventors: Han Ah Chim CHOUNG, Suwon-si (KR); Seok Ryul KIM, Suwon-si (KR); Sung Hyup KIM, Suwon-si (KR); Seung Man KIM, Suwon-si (KR); Sang Hoon LEE, Suwon-si (KR); Byoung Cheol HWANG, Suwon-si (KR)

(73) Assignee: SAMSUNG ELECTRONICS CO., LTD., Suwon-si (KR)

(21) Appl. No.: 19/268,308

(22) Filed: Jul. 14, 2025

(30) Foreign Application Priority Data
Jul. 31, 2024 (KR) 10-2024-0101432

(51) Int. Cl. G06F 30/28; G06F 30/18

(52) U.S. Cl. CPC G06F 30/28; G06F 30/18

(57) ABSTRACT

A fluid analysis method performed by a processor, includes: acquiring shape information about a first pipe and a second pipe, wherein the first pipe comprises an end having a pressure sensor mounted thereat, and a first outlet connected to the end, and wherein the second pipe comprises a second outlet connected to the first pipe and an inlet connected to the second outlet; generating a first simulation model based on the shape information, a first pressure value at the end of the first pipe, and a second pressure value at the inlet of the second pipe; and predicting, using the first simulation model, a flow rate value of fluid flowing into the second pipe and a pressure value of fluid discharged from the first pipe.

### CROSS-REFERENCE TO RELATED APPLICATION

This application is based on and claims priority under 35 U.S.C. § 119 to Korean Patent Application No. 10-2024-0101432, filed on Jul. 31, 2024, in the Korean Intellectual Property Office, the disclosure of which is incorporated by reference herein in its entirety.

### BACKGROUND

The disclosure relates to a fluid analysis method. An apparatus for manufacturing a semiconductor device may include, for example, an apparatus used in a deposition process, an apparatus used in a photoresist process, an apparatus used in an etching process, and an apparatus used in a cleaning process. These apparatuses are disposed in a clean room, and contaminants may be suctioned from the clean room and temperatures of the clean room may be controlled by an exhaust management system.

As the number of these apparatuses increases, the number of pipes connected to the apparatuses also increases. Accordingly, there is an increasing need to accurately predict information about a flow rate and a pressure of fluid flowing through the pipes to manage a fluid exhausted state more precisely.

### SUMMARY

Provided is a fluid analysis method of managing a fluid exhausted state more precisely. The technical purposes of the disclosure are not limited to the technical purposes as mentioned above, and other technical purposes not mentioned will be clearly understood by those skilled in the art from the description as set forth below.

According to an aspect of the disclosure, a fluid analysis method performed by a processor, includes: acquiring shape information about a first pipe and a second pipe, wherein the first pipe comprises an end having a pressure sensor mounted thereat, and a first outlet connected to the end, and wherein the second pipe comprises a second outlet connected to the first pipe and an inlet connected to the second outlet; generating a first simulation model based on the shape information, a first pressure value at the end of the first pipe, and a second pressure value at the inlet of the second pipe; and predicting, using the first simulation model, a flow rate value of fluid flowing into the second pipe and a pressure value of fluid discharged from the first pipe.

According to an aspect of the disclosure, a fluid analysis method performed by a processor, includes: acquiring first shape information about a first pipe and a plurality of second pipes, wherein the first pipe comprises an end having a pressure sensor mounted thereat and a first outlet connected to the end, and wherein each of the plurality of second pipes comprises a second outlet connected to the first pipe and an inlet connected to the second outlet; generating a first simulation model based on the first shape information and a first pressure value measured by the pressure sensor; predicting a pressure value of the fluid discharged from the first pipe using the first simulation model; acquiring second shape information, wherein the first shape information about the first pipe and at least one of the second pipes are changed into the second shape information; generating a second simulation model based on the second shape information and a predicted pressure value of the fluid discharged from the first pipe; and predicting a changed flow rate value of the fluid flowing into each of the plurality of second pipes using the second simulation model.

According to an aspect of the disclosure, a fluid analysis method performed by a processor, includes: acquiring first shape information about a first pipe and a plurality of second pipes, wherein the first pipe comprises an end having a pressure sensor mounted thereat and a first outlet connected to the end, and wherein each of the plurality of second pipes comprises a second outlet connected to the first pipe and an inlet connected to the second outlet; converting the first shape information into drawing data about the first pipe and the plurality of second pipes; applying sensor information measured by the pressure sensor to the drawing data; generating a first simulation model based on the first shape information and the sensor information; acquiring a predicted flow rate value of fluid flowing into each of the plurality of second pipes and a predicted pressure value of the fluid discharged from the first pipe using the first simulation model; and visualizing a fluid exhausted state of each of the first pipe and the plurality of second pipes, based on the predicted flow rate value of the fluid flowing into each of the plurality of second pipes and the predicted pressure value of the fluid discharged from the first pipe.

### BRIEF DESCRIPTION OF THE DRAWINGS

The above and other aspects and features of the disclosure will become more apparent by describing in detail illustrative embodiments of the disclosure with reference to the attached drawings, in which:

FIG. 1 illustrates a fluid analysis system according to some embodiments;

FIG. 2 illustrates a piping system according to some embodiments;

FIG. 3 illustrates components of a piping system according to some embodiments;

FIGS. 4 to 7 illustrate an apparatus and a pipe connected to the apparatus according to some embodiments;

FIG. 8 illustrates prediction of a fluid exhausted state using a first simulation model;

FIG. 9 illustrates selection of fluid exhausted state predicted values based on a loss coefficient in predicting a fluid exhausted state using a first simulation model;

FIG. 10 illustrates prediction of a changed fluid exhausted state using a second simulation model;

FIG. 11 illustrates selecting of fluid exhausted state predicted values based on a loss coefficient when predicting a fluid exhausted state using the second simulation model;

FIG. 12 illustrates a fluid analysis method according to some embodiments;

FIG. 13 illustrates an example of a fluid analysis method performed by a pre-processing code;

FIG. 14a and FIG. 14b each illustrates an example of a fluid analysis method performed by a driver; and

FIG. 15a, FIG. 15b, FIG. 16 and FIG. 17 each illustrate examples of a fluid analysis method performed by a post-processing code.

### DETAILED DESCRIPTIONS

Although terms such as first, second, upper, and lower are used herein to describe various elements or components, it is obvious that these element or components are not limited by the terms. Rather, the terms are merely used herein to distinguish one element or component from another element or component. Therefore, it is obvious that a first element or component as mentioned below may also be a second element or component within the technical spirit of the disclosure. Further, it is obvious that a lower element or component as mentioned below may also be an upper element or component within the technical spirit of the disclosure.

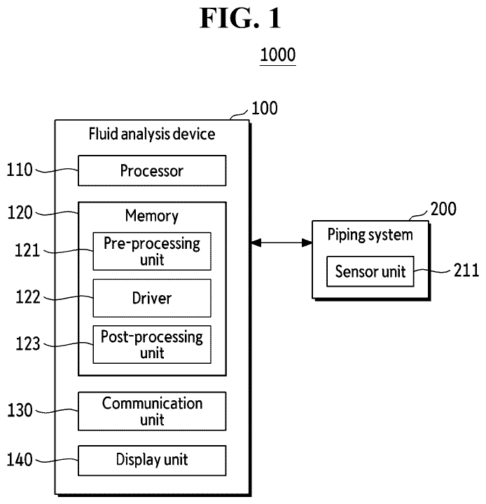

FIG. 1 illustrates a fluid analysis system according to some embodiments.

Referring to FIG. 1, a fluid analysis system 1000 may include a fluid analysis device 100 and a piping system 200. The fluid analysis device 100 may include a processor 110, a memory 120, a communication circuit 130, and a display 140.

The memory 120 may include a pre-processing code 121, a driver 122, and a post-processing code 123.

Each of the pre-processing code 121, the driver 122, and the post-processing code 123 may be implemented, for example, using a processor that may execute software or a program to perform various data processing or calculations. The data processing or calculations may include calculations for performing a simulation of fluid flowing through a pipe, generating a simulation model, and acquiring various predicted values for predicting the fluid exhausted state of the pipe.

The processor may be a data processor built into hardware. Examples of the data processor embedded in the hardware may correspond to or include, but are not limited to, microprocessors, central processing units (CPUs), processor cores, multiprocessors, application-specific integrated circuits (ASICs), and field programmable gate arrays (FPGAs).

The memory 120 may store various data used by the processor. The data may include, for example, input data or output data for software, programs, and commands related to the software or the programs. The memory 120 may include a volatile memory or a nonvolatile memory.

In some embodiments, the memory 120 may store a program for acquiring information about the shapes of pipes and drawing the shape information. Furthermore, the memory 120 may store a program for predicting the fluid exhausted state. Furthermore, the memory 120 may store a program for analyzing and visualizing a fluid exhausted state of pipes. Furthermore, the memory 120 may store pipe information including data about the shape of the pipe and fluid information including data about the pressure, density, and flow rate of the fluid flowing in the pipe.

For example, the memory 120 may include at least one type of storage medium among a flash memory type, a hard disk type, a random access memory (RAM), a static random access memory (SRAM), a read-only memory (ROM), a magnetic memory, a magnetic disk, and an optical disk. However, the disclosure is not limited to the above examples.

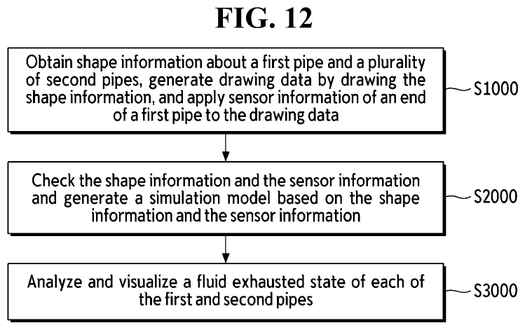

In some embodiments, the pre-processing code 121 may obtain information about the shapes of the pipes and draw the shape information as described below with reference to FIG. 12.

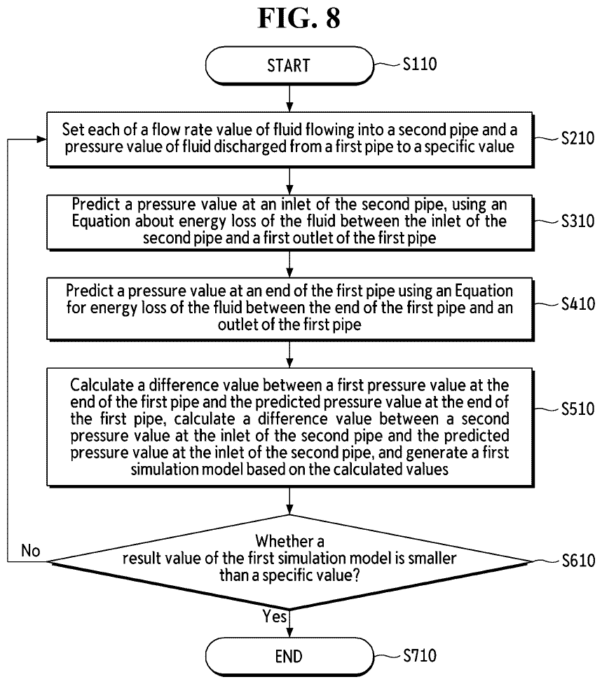

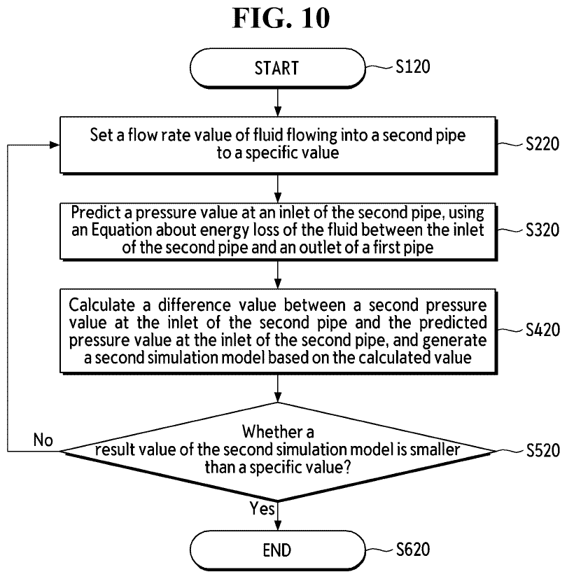

In some embodiments, the driver 122 may generate first and second simulation models as described below with reference to FIG. 8, FIG. 10, and FIG. 12. Using the first and second simulation models, predicted values for predicting the fluid exhausted state of the pipe may be generated. The driver 122 may predict the fluid exhausted state of the pipes connected to the semiconductor manufacturing apparatus using the first simulation. In addition, when a structure of each of the semiconductor manufacturing apparatus and the pipes connected to each of the semiconductor manufacturing apparatus has been changed, the driver 122 may predict the fluid exhausted state according to the changed structure using the second simulation. In some embodiments, the driver 122 may be a program or a computer code.

In some embodiments, the post-processing code 123 may analyze and visualize the fluid exhausted state of the pipes as described later with reference to FIG. 12.

The specific operations as performed by the pre-processing code 121, the driver 122, and the post-processing code 123 will be described later.

The communication circuit 130 may receive a pressure value measured from the piping system 200 in real time. The communication circuit 130 may transmit the received pressure value to the processor 110. Furthermore, the communication circuit may communicate with an external device (e.g., a user terminal or a server). The communication circuit 130 may transmit and receive data indicating the fluid exhausted state of the pipe to and from the external device.

The display 140 may visually provide information to an outside out of the fluid analysis device 100. For example, the display 140 may include a display. The display 140 may display data generated by the processor 110 as a three-dimensional drawing. Furthermore, the display 140 may display a fluid analysis graph generated by the processor 110.

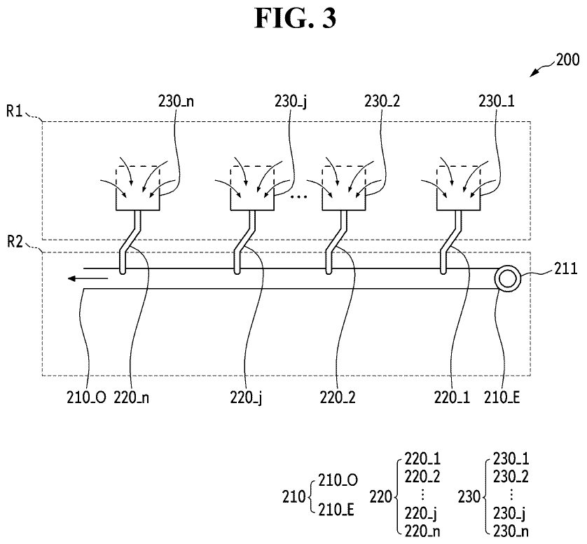

The piping system 200 may include a sensor 211. The sensor 211 may be a pressure sensor. The sensor 211 may be disposed at an end 210_E of FIG. 3 of the first pipe 210 of FIG. 3. The sensor 211 may measure a pressure of the fluid flowing through the pipe. Information about the pressure measured by the sensor 211 may be transmitted to the communication circuit 130 of the fluid analysis device 100.

In this way, the fluid analysis method performed by the pre-processing code 121, the driver 122, and the post-processing code 123 according to some embodiments may be performed by the processor 110.

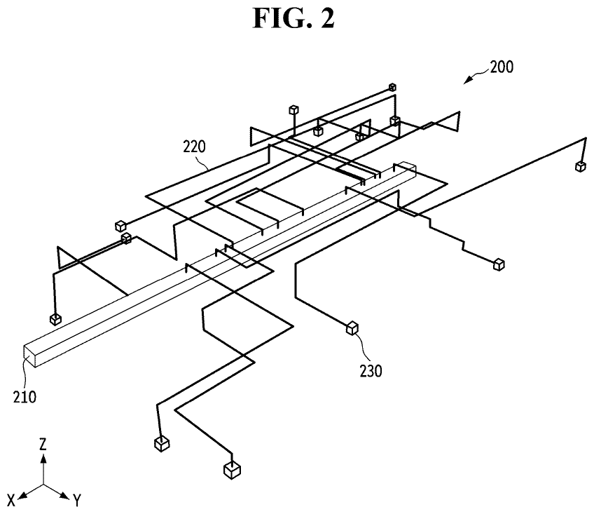

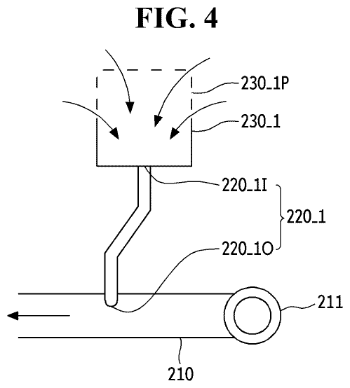

FIG. 2 illustrates a piping system according to some embodiments. FIG. 3 illustrates components of the piping system according to some embodiments. FIGS. 4 to 7 illustrate an apparatus and a pipe connected to the apparatus according to some embodiments.

Referring to FIGS. 2 and 3, the piping system 200 according to some embodiments may include a first pipe 210, a pressure sensor 211, a plurality of second pipes 220, and a plurality of apparatuses 230.

The first pipe 210 may extend in a first direction X. The pressure sensor 211 may be disposed at one end of the first pipe 210 extending in the first direction X. Each of the plurality of apparatuses 230 may be spaced apart from the first pipe 210 in a second direction Y. Each of the plurality of second pipes 220 may connect the first pipe 210 to each of the plurality of apparatuses 230. Each of the plurality of second pipes 220 may extend at least partially in a third direction Z.

In some embodiments, the first and second directions X and Y may intersect each other, and the third direction Z may intersect each of the first and second directions X and Y. Each of the first to third directions X, Y, and Z may intersect each other in an orthogonal direction. However, the disclosure is not limited to the above embodiments.

In a first area R1, the plurality of apparatuses 230 are disposed. The plurality of apparatuses 230 may include, for example, an apparatus used for a deposition process for manufacturing a semiconductor device, an apparatus used for a photoresist process for manufacturing a semiconductor device, an apparatus used for an etching process for manufacturing a semiconductor device, and an apparatus used for a cleaning process for manufacturing a semiconductor device. However, the disclosure is not limited to the above embodiments. The first area R1 may be a clean room in which cleanliness is managed at a considerable level.

In a second area R2, the first pipe 210 is disposed. The second area R2 is an area located under the first area R1 and may be a sub-fab. Each of the plurality of second pipes 220 may extend between the first area R1 and the second area R2 so as to connect each of the plurality of apparatuses 230 to the first pipe 210.

The fluid analysis system 1000 according to some embodiments may be used to suction and discharge contaminants generated in the apparatuses 230 in the clean room R1 and to manage the temperatures of the apparatuses 230. This system may be in a state in which a predetermined amount or greater of fluid may be continuously sucked from the clean room R1 to the apparatuses 230. In this case, an inside of the clean room R1 may be maintained in a positive pressure state (e.g., a pressure greater than or equal to an atmospheric pressure), while an inside of each of the apparatuses 230 may be maintained in a negative pressure state (e.g., a pressure lower than the atmospheric pressure).

The first pipe 210 may include the end 210_E having the pressure sensor 211 mounted thereat and a first outlet 210_O connected to the end 210_E. The plurality of second pipes 220 may include (2-1)-st to (2-n)-th pipes 220_1 to 220_n. The plurality of apparatuses 230 may include first to n-th apparatuses 230_1 to 230_n. In this regard, “n” may be an integer greater than 0.

The plurality of second pipes 220 may be respectively connected to the plurality of apparatuses 230 and may respectively correspond to the plurality of apparatuses 230. The number of the second pipes 220 may be equal to the number of the apparatuses 230.

Referring to FIG. 4, the (2-1)-st pipe 220_1 may include a (2-1)-st outlet 220_1O connected to the first pipe 210 and a (2-1)-st inlet 220_1I connected to the (2-1)-st outlet 220_1O. The (2-1)-st inlet 220_1I may be connected to the first apparatus 230_1.

An intake hole 230_1P into which fluid flows from an outside (for example, R1 in FIG. 3) may be defined in the first apparatus 230_1.

The fluid may be introduced from the outside (e.g., R1 in FIG. 3) through the intake hole 230_1P and may flow through the (2-1)-st inlet 220_1I and the (2-1)-st outlet 220_1O to the first pipe 210.

In this case, for example, a flow rate of the fluid flowing from the outside (e.g., R1 in FIG. 3) through the first apparatus 230_1 and the (2-1)-st pipe 220_1 toward the first outlet 210_O of the first pipe 210 may be referred to as a first flow rate Q₁.

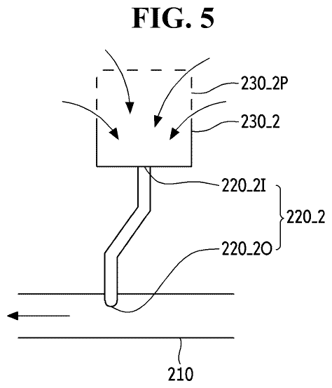

Referring to FIG. 5, the (2-2)-nd pipe 220_2 may include a (2-2)-nd outlet 220_20 connected to the first pipe 210 and a (2-2)-nd inlet 220_21 connected to the (2-2)-nd outlet 220_20. The (2-2)-nd inlet 220_21 may be connected to the second apparatus 230_2.

An intake hole 230_2P into which fluid is introduced from the outside (e.g., R1 in FIG. 3) may be defined in the second apparatus 230_2.

The fluid may be introduced from the outside (e.g., R1 in FIG. 3) through the intake hole 230_2P and may flow through the (2-2)-nd inlet 220_21 and the (2-2)-nd outlet 220_20 to the first pipe 210.

In this case, for example, a flow rate of the fluid flowing from the outside (e.g., R1 in FIG. 3) through the second apparatus 230_2 and the (2-2)-nd pipe 220_2 to the first outlet 210_O of the first pipe 210 may be referred to as a second flow rate Q₂. The fluid of the second flow rate Q₂ may merge with the fluid of the first flow rate Q₁ and the merged fluid may flow toward the first outlet 210_O of the first pipe 210.

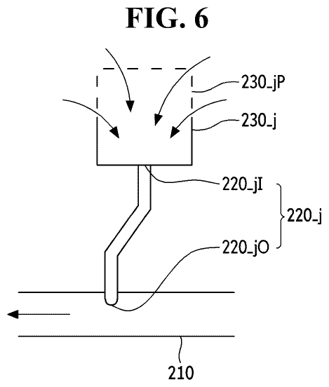

Referring to FIG. 6, a (2-j)-th pipe 220_j may include a (2-j)-th outlet 220_jO connected to the first pipe 210 and a (2-j)-th inlet 220_jI connected to the (2-j)-th outlet 220_jO. The (2-j)-th inlet 220_1I may be connected to a j-th apparatus 230_j. In this regard, j may be any integer from 1 to n.

An intake hole 230_jP into which fluid is introduced from the outside (for example, R1 in FIG. 3) may be defined in the j-th apparatus 230_j.

The fluid may be introduced from the outside (e.g., R1 in FIG. 3) through the intake hole 230_jP and flow through the (2-j)-th inlet 220_jI and the (2-j)-th outlet 220_jO into the first pipe 210.

In this case, for example, a flow rate of the fluid flowing from the outside (e.g., R1 in FIG. 3) through the j-th apparatus 230_j and the (2-j)-th pipe 220_j to the first outlet 210_O of the first pipe 210 may be referred to as a j-th flow rate Qⱼ.

The fluid of the j-th flow rate Qⱼ may merge with the fluid of the first flow rate Q₁. The fluid of the second flow rate Q₂ and the merged fluid may flow toward the first outlet 210_O of the first pipe 210.

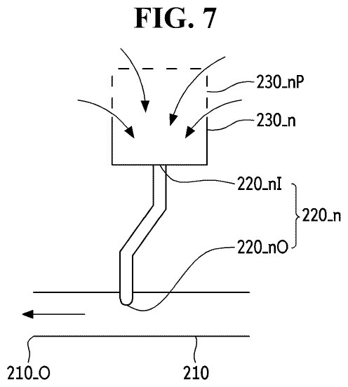

Referring to FIG. 7, the (2-n)-th pipe 220_n may include an (2-n)-th outlet 220_nO connected to the first pipe 210 and an (2-n)-th inlet 220_nI connected to the (2-n)-th outlet 220_nO. The (2-n)-th inlet 220_1I may be connected to the n-th apparatus 230_n.

An intake hole 230_nP into which fluid is introduced from the outside (e.g., R1 in FIG. 3) may be defined in the n-th apparatus 230_n.

The fluid may be introduced from the outside (e.g., R1 in FIG. 3) through the intake hole 230_nP and may flow through the (2-n)-th inlet 220_nI and the (2-n)-th outlet 220_nO to the end 210_E of the first pipe 210.

In this case, for example, a flow rate of the fluid flowing from the outside (e.g., R1 in FIG. 3) through the n-th apparatus 230_n and the (2-n)-th pipe 220_n to the first outlet 210_O of the first pipe 210 may be referred to as an n-th flow rate Qn.

The fluid of the n-th flow rate Qn may merge with the fluid of the first flow rate Q₁, the fluid of the second flow rate Q₂, and the fluid of the j-th flow rate Qⱼ and the merged fluid may be discharged to the first outlet 210_O of the first pipe 210.

The pre-processing code 121 in FIG. 1 may obtain shape information about each of the first pipe 210 and the plurality of second pipes 220 in S1000 in FIG. 12. The shape information may related to at least one of a straight pipe, an elbow pipe, a T-shaped pipe, a reducer, and an orifice. The shape information may include, but is not limited to, information about at least one of relative positions, connection relationships, diameters, lengths, and numbers of the first pipe 210 and the plurality of second pipes 220.

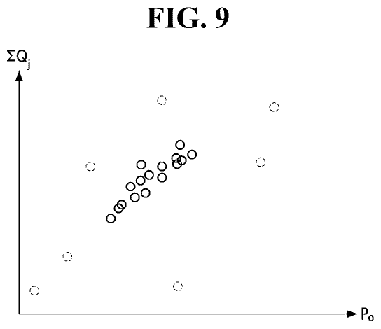

FIG. 8 illustrates prediction of a fluid exhausted state using a first simulation model. FIG. 9 illustrates selection of fluid exhausted state predicted values based on a loss coefficient in predicting a fluid exhausted state using the first simulation model.

Referring to FIG. 3, FIG. 6, and FIG. 8, the driver 122 in FIG. 1 may obtain a first pressure value P̅_{S} at the end 210_E of the first pipe 210. The driver 122 in FIG. 1 may obtain a second pressure value P̅_{J} at the inlet 220_jI of the (2-j)-th pipe 220_j in S110.

The first pressure value P̅_{S} may be obtained using the pressure sensor 211. The second pressure value P̅_{J} may be obtained based on a pressure loss Pₗₒₛₛ that occurs as the fluid flows into the (2-j)-th pipe 220_j.

For example, the second pressure value P̅_{J} may be calculated as a value obtained by subtracting the pressure loss Pₗₒₛₛ that occurs as the fluid flows into the (2-j)-th pipe 220_j from an external pressure (e.g., an atmospheric pressure Pₐₜₘ) to the j-th apparatus 230_j, based on Equation 1 as set forth below:

$${\overline{P}}_{J} = {P}_{atm} - {P}_{l o s s} \qquad Equation 1$$

The pressure loss Pₗₒₛₛ may be determined based on a fluid velocity v, a fluid density ρ, and a fluid loss coefficient k of the fluid flowing into the (2-j)-th pipe 220_j, as expressed in Equation 2 as set forth below.

$${P}_{l o s s} = k \frac{1}{2} ρ {v}^{2} \qquad Equation 2$$

That is, the pressure loss Pₗₒₛₛ may occur due to the fluid flowing from the outside out of the j-th apparatus 230_j toward the j-th apparatus 230_j. The fluid velocity v may be determined based on the flow rate Qⱼ inside the j-th apparatus 230_j.

The driver 122 in FIG. 1 may set each of the flow rate value Qⱼ of the fluid flowing into the (2-j)-th pipe 220_j and a pressure value P_{O} of the fluid discharged from the first pipe 210 to a specific value in S210. This value is an initial setting value and may be reset as described later.

The driver 122 in FIG. 1 may generate the first simulation model fₗₒₛₛ1 in S510. Generating, by the driver 122 in FIG. 1, the first simulation model fₗₒₛₛ1 may include predicting a pressure value Pⱼ at the inlet 220_jI of the (2-j)-th pipe 220_j, using an Equation about energy loss of the fluid between the inlet 220_jI of the (2-j)-th pipe 220_j and the first outlet 210_O of the first pipe 210 in S310.

For example, the above energy loss Equation may predict head loss when the fluid flows in the pipe.

The driver 122 in FIG. 1 may calculate a first difference value P̅_{J}−P_{J} between a second pressure value P̅_{J} and a predicted pressure value Pⱼ at the inlet 220_jI of the (2-j)-th pipe 220_j in S510.

Generating, by the driver 122 in FIG. 1, the first simulation model fₗₒₛₛ1 may include predicting a pressure value Pₛ at the end 210_E of the first pipe 210 using an Equation for energy loss of the fluid between the end 210_E of the first pipe 210 and the outlet 210_O of the first pipe 210 in S410.

For example, the above energy loss Equation may predict head loss when the fluid flows in the pipe.

The driver 122 in FIG. 1 may calculate a second difference value P̅_{S}−P_{S} between a first pressure value Pₛ and a predicted pressure value Pₛ at the end 210_E of the first pipe 210 in S510.

Generating, by the driver 122 in FIG. 1, the first simulation model fₗₒₛₛ1 may include generating a result value of the first simulation model based on the first difference value and the second difference value, based on Equation 3 as set forth below inn nS510.

$${f}_{loss} 1 = {( {\overline{P}}_{S} - {P}_{S} )}^{2} + {\sum }_{j = 1}^{n} {( {\overline{P}}_{J} - {P}_{j} )}^{2} \qquad Equation 3$$

When the result value of the first simulation model fₗₒₛₛ1 is greater than or equal to a specific value, the driver 122 in FIG. 1 may reset the flow rate value Qⱼ of the fluid flowing into the preset second pipe 220_j and the pressure value P_{O} of the fluid discharged from the first pipe 210 using an optimization algorithm in S610.

For example, the optimization algorithm may be, but is not limited to, a Simple Homology Global Optimization (SHGO) algorithm or a Stochastic Gradient Descent (SGD) algorithm.

Resetting, by the driver 122 in FIG. 1, the flow rate value Qⱼ of the fluid flowing into the preset second pipe 220_j and the pressure value P_{O} of the fluid discharged from the first pipe 210 may include quantifying a loss coefficient k of the fluid, and selecting some solutions (at least one solution) from among multiple solutions of the flow rate value Qⱼ of the fluid flowing into the second pipe 220_j and the pressure value P_{O} of the fluid discharged from the first pipe 210, based on the quantified loss coefficient k.

The loss coefficient k is a concept of uncertainty and may be modeled as a normal distribution with a mean and variance. For example, the loss coefficient k may be repeatedly calculated in a range of 0 to 5 at an interval of 0.1. However, the disclosure is not limited to the above numerical values.

FIG. 9 is a diagram showing multiple solutions generated based on the loss coefficient. In FIG. 9, a horizontal axis represents the pressure value P_{O} of the fluid discharged from the first pipe 210, and a vertical axis represents a sum

$${\sum }_{j = 1}^{n} {Q}_{j}$$

of the flow rate values Qⱼ of the fluid flowing into the (2-j)-th pipe 220_j.

Referring to FIG. 9, the flow rate value Qⱼ of the fluid flowing into the (2-j)-th pipe 220_j and the pressure value P_{O} of the fluid discharged from the first pipe 210 may have multiple solutions (P_{O}, Qⱼ) based on the loss coefficient k. For example, data indicated by a solid circle may represent solutions when the loss coefficient k is 5. Data indicated by a dotted circle may represent solutions when the loss coefficient k is not 5, but, for example, 0.3.

Among the multiple solutions, solutions having values within a top 5% may be selected via an algorithm such as conformity ranking. In FIG. 9, the data indicated by the solid circle represents the solutions selected using the conformity ranking. The data indicated by the dotted circle represents the remaining solutions that are not selected.

In this way, the driver 122 in FIG. 1 may obtain finally predicted values of the flow rate value Qⱼ of the fluid flowing into the (2-j)-th pipe 220_j and the pressure value P_{O} of the fluid discharged from the first pipe 210 based on the loss coefficient. In this case, the predicted flow rate value Qⱼ of the fluid flowing into the (2-j)-th pipe 220_j and the predicted pressure value P_{O} of the fluid discharged from the first pipe 210 may be obtained as values in a predetermined range.

Referring back to FIG. 8, when the result value of the first simulation model fₗₒₛₛ1 is smaller than a specific value, the driver 122 in FIG. 1 may finally obtain the predicted flow rate value Qⱼ of the fluid flowing into the (2-j)-th pipe 220_j and the predicted pressure value P_{O} of the fluid discharged from the first pipe 210 in S710.

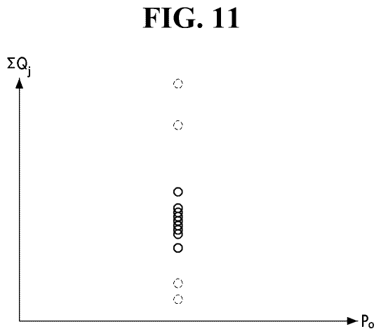

FIG. 10 illustrates prediction of a changed fluid exhausted state using a second simulation model. FIG. 11 illustrates selection of predicted fluid exhausted state values based on the loss coefficient in predicting the fluid exhausted state using the second simulation model.

The pre-processing code 121 in FIG. 1 may obtain changed shape information about at least one of the first pipe 210 and the second pipe 220_j. The changed shape information may include, but is not limited to, information about at least one of a change in relative positions of the first pipe 210 and the plurality of second pipes 220, a change in the connection relationship between the first pipe 210 and the plurality of second pipes 220, a change in the diameter of the first pipe 210 or the plurality of second pipes 220, a change in the length of the first pipe 210 or the plurality of second pipes 220, and a change in the number of the first pipe 210 or the plurality of second pipes 220.

Referring to FIG. 10, first, the driver 122 in FIG. 1 may obtain the predicted pressure value P_{O} of the fluid discharged from the first pipe 210 and the second pressure value P̅_{J} at the inlet 220_jI of the (2-j)-th pipe 220_j in S210. The predicted pressure value P_{O} of the fluid discharged from the first pipe 210 may be a value obtained using the first simulation model fₗₒₛₛ1 as described above using FIG. 8.

The second pressure value P̅_{J} may be obtained using a pressure loss Pₗₒₛₛ that occurs as the fluid flows into the (2-j)-th pipe 220_j.

For example, the second pressure value P̅_{J} may be calculated as a value obtained by subtracting the pressure loss Pₗₒₛₛ that occurs as the fluid flows into the (2-j)-th pipe 220_j from an air pressure (e.g., the atmospheric pressure Pₐₜₘ) outside the apparatus, based on the aforementioned Equation 1.

The pressure loss Pₗₒₛₛ may be determined based on the fluid velocity v, the fluid density ρ, and the fluid loss coefficient k of the fluid flowing into the (2-j)-th pipe 220_j, based on the aforementioned Equation 2. That is, the pressure loss Pₗₒₛₛ may mean the loss caused by the fluid flow from the outside out of the j-th apparatus 230_j toward the j-th apparatus 230_j. The fluid velocity v of the fluid may be determined based on the flow rate Qⱼ inside the j-th apparatus 230_j.

The driver 122 in FIG. 1 may set the flow rate value Qⱼ of the fluid flowing into the 2_j pipe 220_j to a specific value in S220. This value is an initial setting value and may be reset as described below.

The driver 122 in FIG. 1 may generate the second simulation model fₗₒₛₛ2 in S420. Generating, by the driver 122 in FIG. 1, the second simulation model fₗₒₛₛ2 may include predicting the pressure value Pⱼ at the inlet 220_jI of the (2-j)-th pipe 220_j, using an Equation about energy loss of fluid between the inlet 220_jI of the (2-j)-th pipe 220_j and the first outlet 210_O of the first pipe 210 in S320. For example, the above energy loss Equation may predict the head loss when the fluid flows in the pipe.

Generating, by the driver 122 in FIG. 1, the second simulation model fₗₒₛₛ2 may include calculating a difference value P̅_{J}−Pⱼ between the second pressure value P̅_{J} and the predicted pressure value Pⱼ at the inlet 220_jI of the (2-j)-th pipe 220_j in S420.

Generating, by the driver 122 in FIG. 1, the second simulation model fₗₒₛₛ2 may include generating the result value of the second simulation model fₗₒₛₛ2 based on the difference value described above, using an Equation 4 as set forth below in S420.

$${f}_{loss} 2 = {\sum }_{j = 1}^{n} {( {\overline{P}}_{J} - {P}_{j} )}^{2} \qquad Equation 4$$

When the result value of the second simulation model is equal to or greater than a predetermined value, the driver 122 in FIG. 1 may reset the flow rate value Qⱼ of the fluid flowing into the preset second pipe 220_j using an optimization algorithm in S520.

For example, the optimization algorithm may be, but is not limited to, a simple homology global optimization (SHGO) algorithm or a stochastic gradient descent (SGD) algorithm.

Resetting, by the driver 122 in FIG. 1, the flow rate value Qⱼ of the fluid flowing into the preset second pipe 220_j may include quantifying the loss coefficient k of the fluid and selecting some solutions (at least one solution) from among the multiple solutions of the flow rate value Qⱼ of the fluid flowing into the (2-j)-th pipe 220_j based on the quantified loss coefficient k.

The loss coefficient k may be a concept of uncertainty and may be modeled as a normal distribution with a mean and a variance. For example, the loss coefficient k may be repeatedly calculated in a range of 0 to 5 at an interval of 0.1. However, the disclosure is not limited to the above numerical values.

FIG. 11 is a diagram showing multiple solutions generated based on the loss coefficient.

In FIG. 11, a horizontal axis represents the pressure value P_{O} of the fluid discharged from the first pipe 210, and a vertical axis represents a sum

$${\sum }_{j = 1}^{n} {Q}_{j}$$

of the flow rate values Qⱼ of the fluid flowing into the (2-j)-th pipe 220_j.

Referring to FIG. 11, the flow rate value Qⱼ of the fluid flowing into the (2-j)-th pipe 220_j has multiple solutions based on the loss coefficient k. In this case, unlike FIG. 9, the pressure value P_{O} of the fluid discharged from the first pipe 210 is fixed to one value.

Solutions having values within a top 5% among the multiple solutions may be selected via an algorithm such as conformity ranking. In FIG. 11, data indicated by a solid line circle represents the solutions selected via the conformity ranking. Data indicated by a dotted line circle represents the remaining solutions that are not selected.

In this way, the driver 122 in FIG. 1 may obtain the final predicted value of the flow rate value Qⱼ of the fluid flowing into the (2-j)-th pipe 220_j based on the loss coefficient. In this case, the predicted flow rate value Qⱼ of the fluid flowing into the (2-j)-th pipe 220_j may be obtained as a value in a predetermined range.

Referring to FIG. 10 again, when the result value of the second simulation model fₗₒₛₛ2 is smaller than a specific value, the driver 122 in FIG. 1 may finally obtain the predicted flow rate value Qⱼ of the fluid flowing into the (2-j)-th pipe 220_j in S620. In addition, the driver 122 in FIG. 1 may predict a changed pressure value Pₛ at the end 210_E of the first pipe 210 using the second simulation model fₗₒₛₛ2.

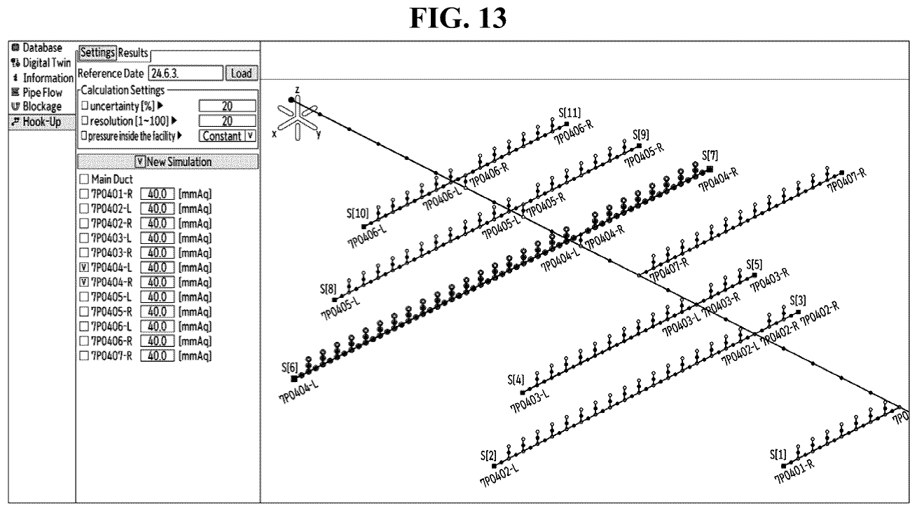

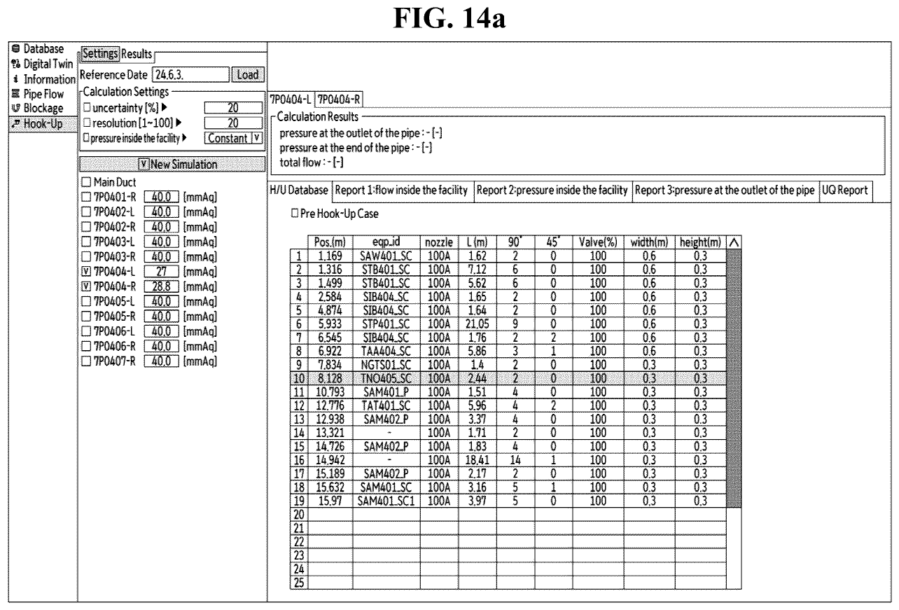

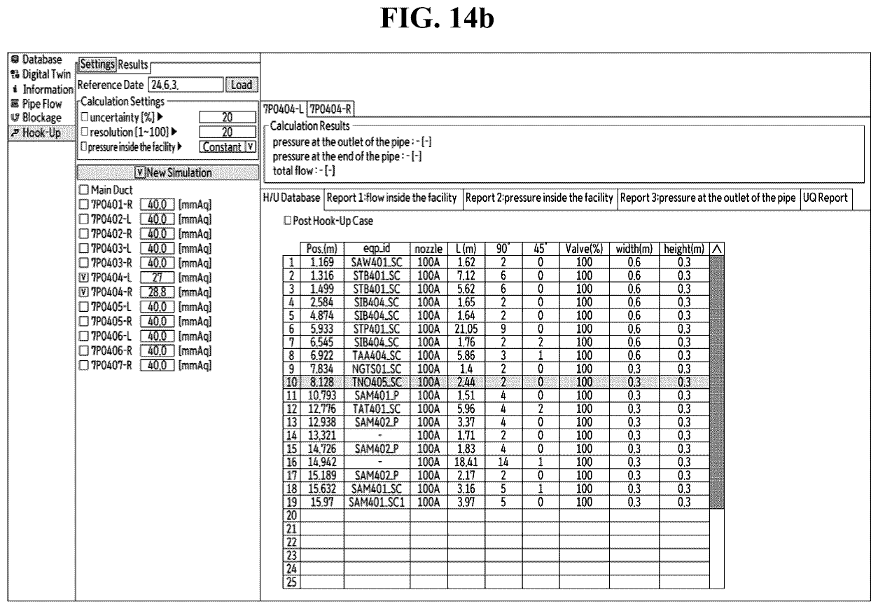

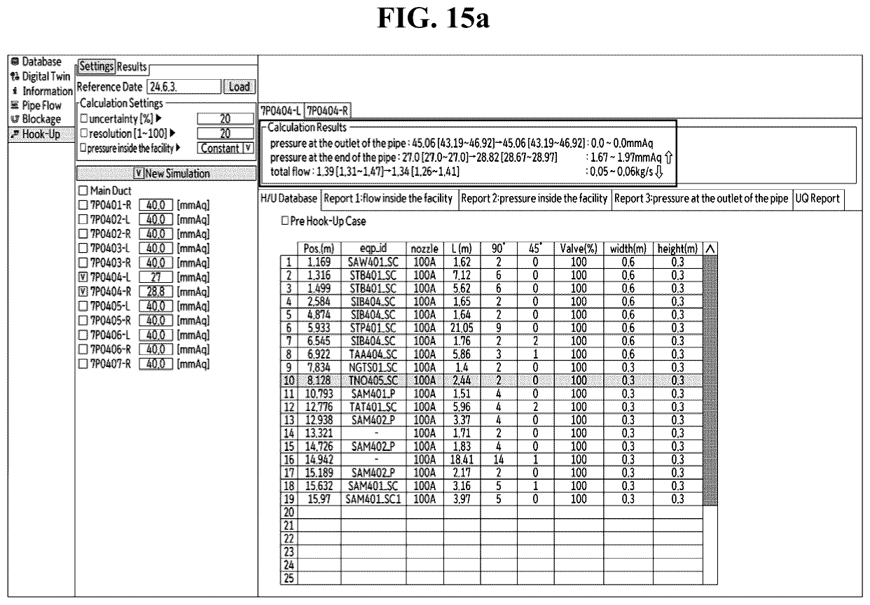

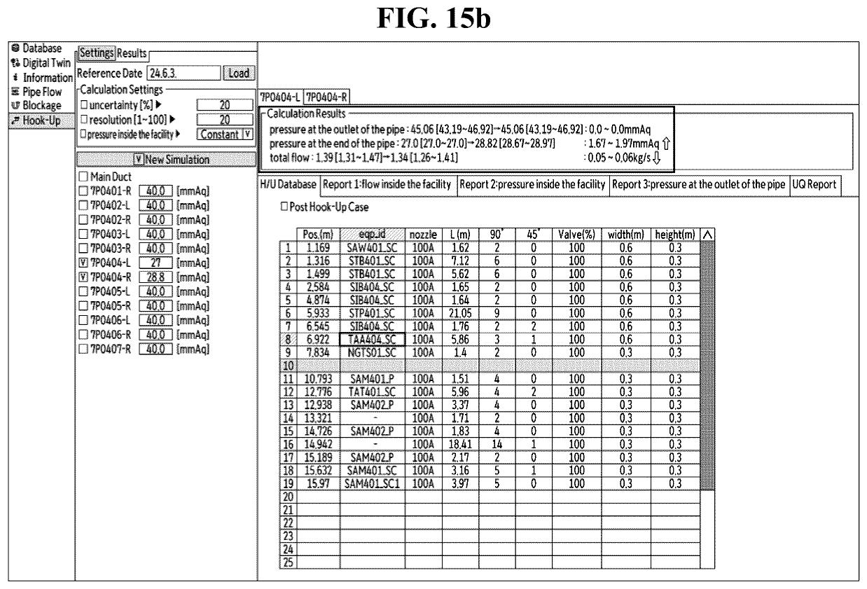

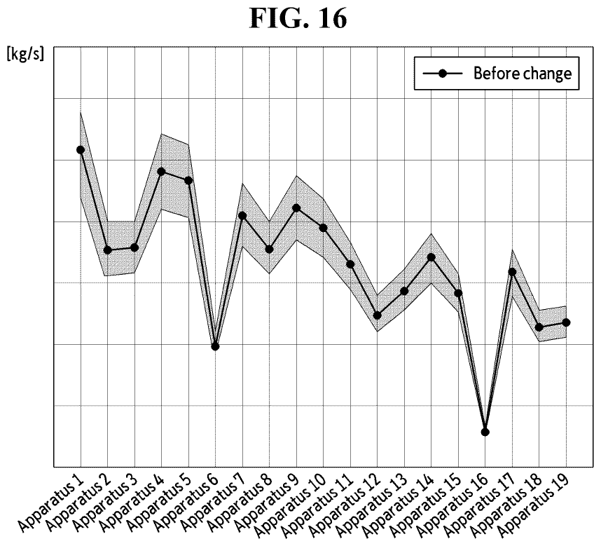

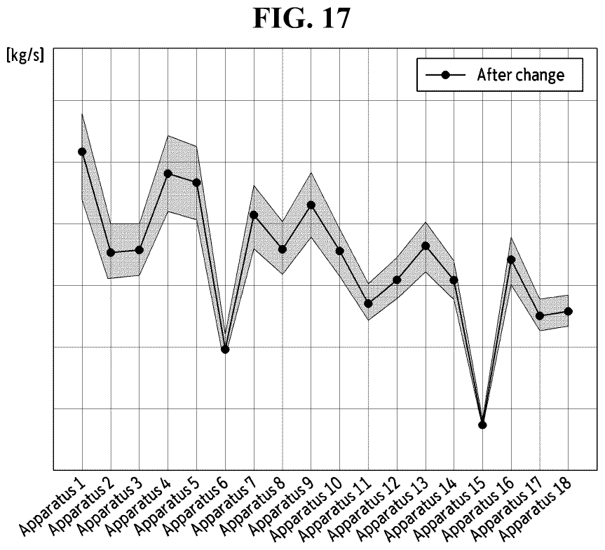

FIG. 12 is a flowchart illustrating a fluid analysis method according to some embodiments. FIG. 13 illustrates an example of a fluid analysis method performed by a pre-processing code. FIG. 14a and FIG. 14b each illustrates an example of a fluid analysis method performed by a driver. FIG. 15a, FIG. 15b, FIG. 16 and FIG. 17 each illustrate examples of a fluid analysis method performed by a post-processing code. For reference, FIG. 16 and FIG. 17 illustrate fluid exhausted states before and after a structure of the pipes is changed, respectively.

Referring to FIG. 12 and FIG. 13, the pre-processing code 121 of FIG. 1 may generate drawing data by drawing shape information about the shapes of the first pipe 210 and the plurality of second pipes 220 in S1000. The shape information may be acquired, edited, and managed as text data. The drawing data may be a drawing of text data. Thus, a prediction target pipe may be selected from among the pipes indicated in the drawing, as shown in FIG. 13.

Furthermore, the pre-processing code 121 of FIG. 1 may apply sensor information of the end 210_E of FIG. 3 of the first pipe 210 of FIG. 3 to the drawing data in S1000. That is, according to the fluid analysis device 100 according to some embodiments, not only simple drawing data but also sensor information may be displayed on the drawing in an associated manner with each other.

As described above, the shape information may include, but is not limited to, information about at least one of the relative positions, the connection relationships, the diameters, the lengths, and the numbers of the first pipe 210 and the plurality of second pipes 220. The sensor information may be information about pressure measured by the pressure sensor 211 in FIG. 3.

Thereafter, referring to FIG. 12, FIG. 14a and FIG. 14b, the driver 122 in FIG. 1 may check the shape information and the sensor information and generate a simulation model based on the shape information and the sensor information in S2000. When the shape information has been changed, the shape information before the change and the shape information after the change may be respectively modified, as shown in FIG. 14a and FIG. 15b and may be compared with each other. Although not specifically shown, the shape information before the change and the shape information after the change may be modified on both sheets and compared with each other. The simulation model may be the first simulation model fₗₒₛₛ1 and/or the second simulation model fₗₒₛₛ2 as described above. Accordingly, the driver 122 of FIG. 1 may generate predicted values of the fluid exhausted states of the first pipe 210 and the plurality of second pipes 220.

For example, the driver 122 of FIG. 1 may check the shape information and the sensor information, and generate the first simulation model fₗₒₛₛ1 based on the shape information and the sensor information. The driver 122 of FIG. 1 may obtain the predicted flow rate value Qⱼ of the fluid flowing into each of the plurality of second pipes 220_1 to 220_n and the predicted pressure value P_{O} of the fluid discharged from the first pipe 210 using the first simulation model fₗₒₛₛ1.

In one example, when the shape information has been changed, the driver 122 of FIG. 1 may identify the changed shape information and generate the second simulation model fₗₒₛₛ2 based on the changed shape information and the predicted pressure value P_{O} of the fluid discharged from the first pipe 210. The driver 122 of FIG. 1 may predict the changed flow rate value Qⱼ of the fluid flowing into each of the plurality of second pipes 220 and the changed pressure value Pₛ at the end 210_E of the first pipe 210 using the second simulation model fₗₒₛₛ 2.

Thereafter, referring to FIG. 12, FIG. 15a, FIG. 15b, FIG. 16 and FIG. 17, the post-processing code 123 of FIG. 1 may perform analysis on the fluid exhausted state based on the predicted values and generate visualized information on the fluid exhausted state based on the analysis result in S3000.

The post-processing code 123 in FIG. 1 may analyze and visualize the fluid exhausted state of each of the first pipe 210 and the plurality of second pipes 220_1 to 220_n based on the predicted flow rate value Qⱼ of the fluid flowing into each of the plurality of second pipes 220_1 to 220_n and the predicted pressure value P_{O} of the fluid discharged from the first pipe 210.

In one example, when the shape information has been changed, the post-processing code 123 in FIG. 1 may analyze and visualize the fluid exhausted state of each of the first pipe 210 and the plurality of second pipes 220_1 to 220_n based on the predicted value of the changed flow rate value Qⱼ of the fluid flowing into each of the plurality of second pipes 220 and the changed pressure value Pₛ at the end 210_E of the first pipe 210.

Referring to FIG. 15a and FIG. 15b, when one of the plurality of second pipes 220_1 to 220_n and one of the plurality of apparatuses 230 connected thereto have been removed such that the shape information has been changed, the post-processing code 123 in FIG. 1 may check the analysis result of the fluid exhausted state. For example, as shown in FIG. 15a and FIG. 15b, it may be identified that the predicted pressure value P_{O} of the fluid discharged from the first pipe 210 does not substantially change significantly, but the pressure value Pₛ at the end 210_E of the first pipe 210 increases, and the changed flow rate value Qⱼ of the fluid flowing into each of the plurality of second pipes 220 decreases.

Furthermore, referring to FIG. 16 and FIG. 17, the post-processing code 123 in FIG. 1 may indicate the fluid exhausted state of each of the plurality of second pipes 220_1 to 220_n and each of the plurality of apparatuses 230 as a graph including uncertainty. That is, an error range based on the aforementioned loss coefficient k may be indicated in the graph. In the graph in FIG. 16 and FIG. 17, a horizontal axis represents the apparatuses, and a vertical axis represents the flow rate (kg/sec) of the apparatus.

Referring to FIG. 16, the post-processing code 123 in FIG. 1 may indicate the fluid exhausted state of each of, for example, 19 apparatus and the pipes respectively connected thereto as a graph.

Referring to FIG. 17, the post-processing code 123 in FIG. 1 may indicate the fluid exhausted state of, for example, 18 apparatuses and the pipes respectively connected thereto as a graph. That is, this case may mean that one of the 19 apparatuses has been removed and thus, the shape information has been changed.

Furthermore, the post-processing code 123 in FIG. 1 may generate a contour image of a pressure distribution in the pipe. The image may be identified using 3D rendering.

In some embodiments, the fluid analysis method may be used to more precisely predict the fluid exhausted state and the temperature management status of the apparatus using the simulation model. In particular, using a single pressure sensor 211, the piping system may be designed efficiently while optimized exhausted state prediction is performed. Furthermore, from the perspective of a user using a program, the exhausted state prediction and analysis may be performed more easily based on the drawing associated with the sensor.

Although embodiments of the disclosure have been described with reference to the accompanying drawings, the disclosure is not limited to the above embodiments, but may be implemented in various different forms. A person skilled in the art may appreciate that the disclosure may be practiced in other concrete forms without changing the technical spirit or essential characteristics of the disclosure. Therefore, the embodiments as described above is not restrictive but illustrative in all respects.

What is claimed is:

1. A fluid analysis method performed by a processor, the method comprising:
acquiring shape information about a first pipe and a second pipe,
wherein the first pipe comprises an end having a pressure sensor mounted thereat, and a first outlet connected to the end, and
wherein the second pipe comprises a second outlet connected to the first pipe and an inlet connected to the second outlet;
generating a first simulation model based on the shape information, a first pressure value at the end of the first pipe, and a second pressure value at the inlet of the second pipe; and
predicting, using the first simulation model, a flow rate value of fluid flowing into the second pipe and a pressure value of fluid discharged from the first pipe.

2. The fluid analysis method of claim 1, wherein the first pressure value is acquired by a pressure sensor, and
wherein the second pressure value is acquired based on a pressure loss occurring as the fluid flows into the second pipe.

3. The fluid analysis method of claim 2, wherein the pressure loss is determined based on a fluid velocity of the fluid flowing into the second pipe, a density of the fluid, and a loss coefficient of the fluid.

4. The fluid analysis method of claim 1, wherein the generating of the first simulation model includes:
predicting a pressure value at the inlet of the second pipe based on energy loss of the fluid between the inlet of the second pipe and the first outlet of the first pipe; and
calculating a difference value between the second pressure value and the predicted pressure value at the inlet of the second pipe.

5. The fluid analysis method of claim 1, wherein the generating of the first simulation model comprises:
predicting a pressure value at the end of the first pipe based on energy loss of the fluid between the end of the first pipe and the outlet of the first pipe; and
calculating a difference value between the first pressure value and the predicted pressure value at the end of the first pipe.

6. The fluid analysis method of claim 1, wherein the generating of the first simulation model comprises generating a result value of the first simulation model,
wherein the fluid analysis method further comprises:
when the result value is equal to or greater than a predefined value, resetting a flow rate value of the fluid flowing into a preset second pipe and the pressure value of the fluid discharged from the first pipe using an optimization algorithm.

7. The fluid analysis method of claim 6, wherein the optimization algorithm comprises a simple homology global optimization algorithm or a stochastic gradient descent algorithm.

8. The fluid analysis method of claim 6, wherein the resetting of the flow rate value of the fluid flowing into the preset second pipe and the pressure value of the fluid discharged from the first pipe using the optimization algorithm comprises selecting at least one solution from multiple solutions of the flow rate value of the fluid flowing into the preset second pipe and the pressure value of the fluid discharged from the first pipe, using a conformity ranking algorithm.

9. The fluid analysis method of claim 1, wherein the shape information comprises at least one of relative positions, a connection relationship, diameters, lengths, and a number of the first pipe and the second pipe.

10. The fluid analysis method of claim 1, further comprising:
acquiring changed shape information on at least one of the first pipe and the second pipe;
generating a second simulation model based on the changed shape information and the predicted pressure value of the fluid discharged from the first pipe; and
predicting a changed flow rate value of the fluid flowing into the second pipe and a changed pressure value at the first end of the first pipe, using the second simulation model.

11. The fluid analysis method of claim 10, wherein the generating of the second simulation model comprises:
predicting a pressure value at the inlet of the second pipe based on energy loss of fluid between the inlet of the second pipe and the first outlet of the first pipe; and
calculating a difference value between the second pressure value and the predicted pressure value at the inlet of the second pipe.

12. The fluid analysis method of claim 11, wherein the generating of the second simulation model further comprises generating a result value of the second simulation model, based on the difference value,
wherein the method further comprises:
when the result value is equal to or greater than a predefined value, resetting the flow rate value of the fluid flowing into a preset second pipe.

13. The fluid analysis method of claim 12, wherein the resetting of the flow rate value of the fluid flowing into the preset second pipe comprises selecting at least one solution from multiple solutions of the flow rate value of the fluid flowing into the second pipe, using a conformity ranking algorithm.

14. A fluid analysis method performed by a processor, comprising:
acquiring first shape information about a first pipe and a plurality of second pipes,
wherein the first pipe comprises an end having a pressure sensor mounted thereat and a first outlet connected to the end, and
wherein each of the plurality of second pipes comprises a second outlet connected to the first pipe and an inlet connected to the second outlet;
generating a first simulation model based on the first shape information and a first pressure value measured by the pressure sensor;
predicting a pressure value of the fluid discharged from the first pipe using the first simulation model;
acquiring second shape information, wherein the first shape information about the first pipe and at least one of the second pipes are changed into the second shape information;
generating a second simulation model based on the second shape information and a predicted pressure value of the fluid discharged from the first pipe; and
predicting a changed flow rate value of the fluid flowing into each of the plurality of second pipes using the second simulation model.

15. The fluid analysis method of claim 14, wherein the generating of the first simulation model further comprises generating the first simulation model based on a second pressure value of the fluid flowing into each of the plurality of second pipes, and
wherein the second pressure value is obtained based on a pressure loss occurring as the fluid flows into each of the plurality of second pipes.

16. The fluid analysis method of claim 14, wherein the generating of the second simulation model further comprises generating the second simulation model, based on a second pressure value of the fluid flowing into each of the plurality of second pipes, and
wherein the second pressure value is obtained based on a pressure loss occurring as the fluid flows into each of the plurality of second pipes.

17. The fluid analysis method of claim 14, further comprising predicting a flow rate value of the fluid flowing into each of the plurality of second pipes using the first simulation model.

18. The fluid analysis method of claim 14, further comprising predicting a changed pressure value at the end of the first pipe using the second simulation model.

19. A fluid analysis method performed by a processor, comprising:
acquiring first shape information about a first pipe and a plurality of second pipes,
wherein the first pipe comprises an end having a pressure sensor mounted thereat and a first outlet connected to the end, and
wherein each of the plurality of second pipes comprises a second outlet connected to the first pipe and an inlet connected to the second outlet;
converting the first shape information into drawing data about the first pipe and the plurality of second pipes;
applying sensor information measured by the pressure sensor to the drawing data;
generating a first simulation model based on the first shape information and the sensor information;
acquiring a predicted flow rate value of fluid flowing into each of the plurality of second pipes and a predicted pressure value of the fluid discharged from the first pipe using the first simulation model; and
visualizing a fluid exhausted state of each of the first pipe and the plurality of second pipes, based on the predicted flow rate value of the fluid flowing into each of the plurality of second pipes and the predicted pressure value of the fluid discharged from the first pipe.

20. The fluid analysis method of claim 19, further comprising:
acquiring second shape information, wherein the first shape information about the first pipe and at least one of the second pipes are changed into the second shape information;
generating a second simulation model based on the second shape information and a predicted pressure value of the fluid discharged from the first pipe;
predicting a changed flow rate value of the fluid flowing into each of the plurality of second pipes and a changed pressure value at the end of the first pipe, using the second simulation model; and
visualizing a changed fluid exhausted state of each of the first pipe and the at least one of the plurality of second pipes, based on the changed flow rate value and the changed pressure value.
